(19) United States
(12) Patent Application Publication
(10) Pub. No.: US 2010/0065318 A1
(43) Pub. Date: Mar. 18, 2010

(54) CIRCUIT BOARD AND SEMICONDUCTOR ELEMENT MOUNTED STRUCTURE USING THE SAME

(75) Inventors: Tadashi Nagasawa, Shiga (JP); Kiyomi Hagihara, Shiga (JP); Katsura Hayashi, Shiga (JP)

Correspondence Address: BIRCH STEWART KOLASCH & BIRCH, PO BOX 747, FALLS CHURCH, VA, 22040-0747, US

(73) Assignee: KYOCERA CORPORATION, Kyoto (JP)

(21) Appl. No.: 12/516,751

(22) PCT Filed: Nov. 27, 2007
(86) PCT No.: PCT/JP2007/072874

§ 371 Date: Aug. 3, 2009

(30) Foreign Application Priority Data
Nov. 28, 2006 (JP) 2006-320029

(51) Int. Cl. H05K 1/16; H05K 1/11

(52) U.S. Cl. 174/260; 174/262

(57) ABSTRACT

A circuit board according to an embodiment of the present invention relates to a circuit board 2 including an insulating layer 7 and a via conductor 8 embedded in the insulating layer 7. The via conductor 8 has a narrowed portion 80 inclined with respect to a horizontal direction X.

### TECHNICAL FIELD

The present invention relates to a circuit board and a semiconductor element mounted structure using the same.

### BACKGROUND ART

There has been known a mounted structure in which a semiconductor element such as IC (Integrated Circuit), LSI (Large Scale Integration), or the like is mounted on a circuit board.

As a circuit board, for example, there is a structure in that a plurality of insulating layers and a plurality of conductor layers are stacked, and the conductor layers are connected to each other through via conductors (refer to, for example, Patent Document 1).

In such a circuit board, the number of the insulating layers and conductor layers stacked tends to increase for achieving higher-density circuit with recent miniaturization of electronic apparatuses.

On the other hand, as a via conductor in a circuit board, a tapered via conductor is used, in which the width decreases from one of the ends to the other end. When such a tapered via conductor is used, the contact area at the interface between the via conductor and the conductor layer at one of the ends is larger than that at the other end. Therefore, stress is easily concentrated at the interface between the other end and the conductor layer, thereby causing the problem in which the via conductor easily separates from the conductor layer. Separation of the via conductor may cause conduction defects in the circuit board, causing a decrease in yield of the circuit board.

[Patent Document 1] Japanese Unexamined Patent Application Publication No. 8-116174

### DISCLOSURE OF INVENTION

### Problems to be Solved by the Invention

The present invention provides a circuit board with good reliability in which separation of a via conductor is effectively decreased, and a semiconductor element mounted structure using the circuit board.

### Means for Solving the Problems

In order to resolve the problem, a circuit board according to a first embodiment of the present invention includes an insulating layer and a via conductor embedded in the insulating layer, the via conductor including a narrowed portion inclined with respect to a horizontal direction along a surface of the insulating layer.

A circuit board according to a second embodiment of the present invention includes an insulating layer and a via conductor embedded in the insulating layer, the via conductor having a concave surface which is recessed toward the inside of the via conductor and a cross section of the via conductor which is formed by plotting positions of the recessed portion along the circumferential direction of the via conductor being inclined with respect to a plane parallel to the surface of the insulating layer.

### ADVANTAGES

According to the circuit board of the present invention, separation of a via conductor in the circuit board can be effectively decreased, thereby contributing to improvement in yield of the circuit board and a semiconductor element mounted structure using the circuit board.

### BRIEF DESCRIPTION OF DRAWINGS

FIG. 1 is a sectional view of a semiconductor element mounted structure according to an embodiment of the present invention.

FIG. 2 is an enlarged sectional view showing the periphery of a via conductor in the mounted structure shown in FIG. 1.

FIG. 3 is a perspective view of a via conductor in the semiconductor element mounted structure shown in FIG. 1.

FIG. 4 is a sectional view showing the periphery of a through hole in which a via conductor is formed in the semiconductor element mounted structure shown in FIG. 1 together with an energy distribution when the through hole is formed.

### REFERENCE NUMERALS

1 mounted structure
2 circuit board
3 semiconductor element
4 bump
6 conductor layer
7 insulating layer
70 adhesive layer
71 film layer
8 via conductor
80 narrowed portion
81 convex portion
A inclination angle
X horizontal direction
Y thickness direction (perpendicular to the X direction)

### BEST MODE FOR CARRYING OUT THE INVENTION

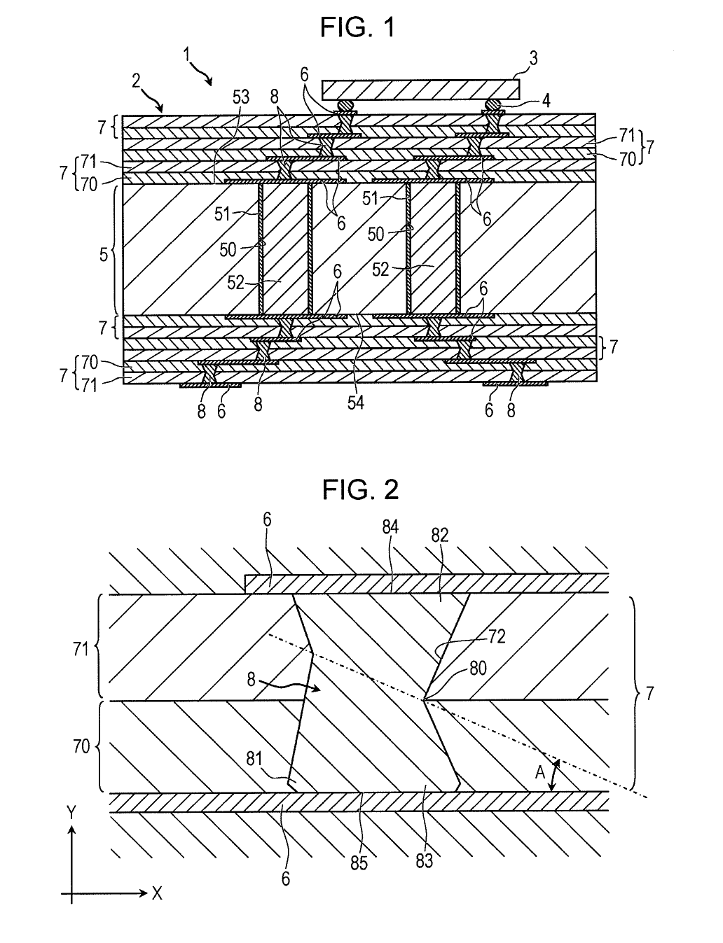

A circuit board and a semiconductor element mounted structure according to an embodiment of the present invention are described in detail below with reference to FIGS. 1 to 4.

A semiconductor element mounted structure 1 shown in FIG. 1 is used for, for example, electronic apparatuses such as various audio-visual apparatuses, household electric appliances, communication apparatuses, computer devices and peripheral devices thereof. The mounted structure 1 includes a circuit board 2 and a semiconductor element 3 mounted on the circuit board 2.

The semiconductor element 3 is IC, LSI, or the like, which is composed of silicon as a base material, and is mounted on the circuit board 2 through bumps 4 such as solder.

The circuit board 2 is adapted for constructing transmission paths for transmitting electric signals. The circuit board 2 includes a core substrate 5 formed in a plate shape and a plurality of conductor layers 6 and a plurality of insulating layers 7 which are alternately stacked on the upper surface 53 and the lower surface 54 of the core substrate 5.

The core substrate 5 has insulation and can be formed by, for example, stacking sheets including woven fabrics impregnated with a thermosetting resin and solidifying the resultant stack. As the woven fabrics, a glass cloth formed by weaving glass fibers lengthwise and crosswise can be used. As the thermosetting resin, an epoxy resin, a bismaleimide triazine resin, or a cyanate resin can be used. The core substrate 5 can be made of ceramic. As the ceramic of the core substrate 5, oxide ceramic such as an aluminum oxide sintered body, a mullite sintered body, or the like, or non-oxide ceramic such as an aluminum nitride sintered body, a silicon carbide sintered body, or the like can be used.

The core substrate 5 has through holes 50 which pass through the core substrate 5 in the thickness direction. In each of the through holes 50, a through hole conductor 51 and an insulator 52 are formed. The through hole conductor 51 is adapted for electrically connecting the conductor layers 6 formed on the upper surface 53 and the lower surface 54 of the core substrate 5, which are described below. The through hole conductor 51 is formed on the inner surface of each through hole 50 using a conductive material. The through hole conductor 51 can be formed by, for example, copper plating. The insulator 52 is adapted for securing flatness of the core substrate 5 and can be formed by filling each of the through holes 50 with an insulating resin after the through hole conductor 51 is formed.

The plurality of conductor layers 6 function as transmission paths for transmitting electrical signals. Each of the conductor layers 6 has conductivity and is made of a metallic material, e.g., copper, silver, gold, aluminum, nickel, chromium, or the like. The plurality of conductor layers 6 are stacked above and below the core substrate 5 with the insulating layers 7 provided between the respective conductor layers 6 and include the conductor layers 6 formed on the upper surface 53 and the lower surface 54 of the core substrate 5. The conductor layers 6 formed on the upper surface 53 and the lower surface 54 of the core substrate 5 are electrically connected to each other through the through hole conductors 51 and are partially formed on the upper surface 53 and the lower surface 54 of the core substrate 5 in order to form circuit patterns.

The plurality of insulating layers 7 are adapted for securing insulation between the conductor layers 6 and each include an adhesive layer 70 and a film layer 71.

The adhesive layer 70 is adapted for bonding the insulating layers 71 together and fixing the film layer 71 to the conductor layer 6 and is formed to cover the conductor layer 6.

The film layer 71 is adapted for improving rigidity of the whole substrate and is formed to cover the adhesive layer 70.

Each of the adhesive layer 70 and the film layer 71 is formed using an insulating material so that, for example, the thickness after drying is 1 μm to 10 μm. The thickness of the film layer 71 is preferably determined to be larger than the thickness of the adhesive layer 70, and, for example, the difference in thickness between the film layer 71 and the adhesive layer 70 is 7 μm or less. The difference in thickness between the film layer 71 and the adhesive layer 70 represents the difference in thickness between both layers after the adhesive layer 70 is dried.

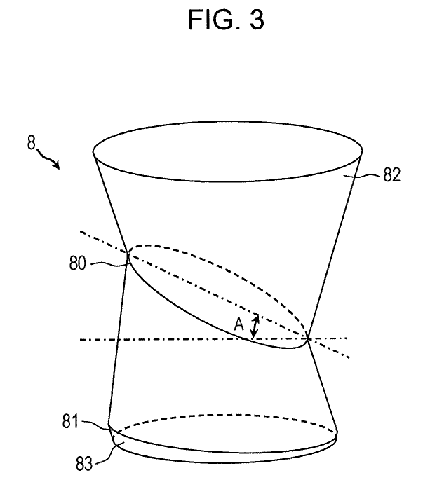

If the thickness of the film layer 71 is larger than the thickness of the adhesive layer 70, and the difference in thickness between both layers is 7 μm or less, a narrowed portion 80 (refer to FIGS. 2 and 3) of a via conductor 8 can be appropriately formed when the via conductor 8 is formed by a production method which is described below, thereby contributing to improvement in yield of the circuit board 2.

The adhesive layer 70 is formed so that, for example, the thermal decomposition temperature is 260° C. to 320° C., and the film layer 71 is formed so that, for example, the thermal decomposition temperature is 380° C. to 520° C. The difference in thermal decomposition temperature between the adhesive layer 70 and the film layer 71 is preferably 60° C. to 260° C. The thermal decomposition temperature refers to the temperature at which when heat is applied to a solidified resin, the resin partially disappears by decomposition, evaporation, or sublimation, and the weight of the resin decreases by 5%.

The adhesive layer 70 and the film layer 71 can be formed by, for example, bonding together the adhesive layer 70 and the film layer 71 each made of a resin material, stacking the resulting laminate on the core substrate 5 or the conductor layer 6, and then solidifying the resin by heating and pressing the laminate with a hot press apparatus. Of course, the adhesive layer 70 and the film layer 71 can be formed by forming a resin layer as the adhesive layer 7 on the core substrate 5 or the conductor layer 6, laminating the film layer 71, and then solidifying the resin by heating and pressing the laminate.

As the resin material for the adhesive layer 70, for example, at least one of a polyimide resin, an acryl resin, an epoxy resin, a cyanate resin, a urethane resin, a silicone resin, and a bismaleimide triazine resin can be used. On the other hand, as the resin material for the film layer 71, for example, at least one of a polybenzoxazole resin, a polyimide resin, a wholly aromatic polyamide resin, a wholly aromatic polyester resin, and a liquid crystal polymer resin can be used. When a polyimide resin is used as the material for the adhesive layer 70, the film layer 71 is preferably formed using a polybenzoxazole resin having good adhesion to the adhesive layer 70.

The adhesive layer 70 may contain a spherical filler having insulation. In such an adhesive layer 70, when a hole is formed in the adhesive layer 70, irregularity occurs in the inner surface of the through hole due to the exposed spherical filler and a portion in which the spherical filler is absent. Therefore, the via conductor 8 which will be described below increases in adhesion to the adhesive layer 70 in a portion of the adhesive layer 70 in which the via conductor 8 is present.

Further, the via conductors 8 are formed in the insulating layers 7 so as to pass through the insulating layers 7 in the thickness direction. The via conductors 8 are adapted to electrically connect together different conductor layers 6 disposed with the insulating layers 7 provided between the respective conductor layers 6, and are embedded in the through holes 72 of the insulating layers 7 as shown in FIGS. 1 and 2.

As shown in FIGS. 2 and 3, each of the via conductors 8 includes a narrowed portion 80 and a projecting portion 81 and is made of a conductive material, e.g., copper, silver, gold, aluminum, nickel, chromium, or the like. The via conductor 8 is tapered between an end 82 and the narrowed portion 80 so that the width of the via conductor 8 decreases toward the narrowed portion 80 between the end 82 and the narrowed portion 80. The via conductor 8 is tapered between the projecting portion 81 and the narrowed portion 80 so that the width of the via conductor 8 decreases toward the narrowed portion 80 between the end 82 and the narrowed portion 80. That is, the via conductor 8 has a concave surface recessed toward the inside of the via conductor 8 and a section of the via conductor 8 (section of the narrowed portion 80) formed by plotting the recessed portion along the circumferential direction of the via conductor 8 is inclined with respect to a plane parallel to the surface of the insulating layer 7. In the via conductor 8 having such a shape, even when force is applied to the insulating layer 7 in the thickness direction Y, a portion of the via conductor 8 closely adheres to the insulating layer 7, and a portion of the via conductor 8 provides reaction in the direction opposite to the applied force, thereby decreasing separation of the insulating layer 7 from the conductor layer 6.

The narrowed portion 80 disperses stress exerted on the interfaces 84 and 85 between the conductor layers 6 and the ends 82 and 83 of the via conductor 8. The narrowed portion 80 is formed in an elliptic circular shape as a whole and is inclined with respect to the horizontal direction X. The inclination angle A of the narrowed portion 8 with respect to the horizontal direction X is, for example, 10° to 20°. As a result, it is possible to effectively reduce the stress exerted between the end 83 of the via conductor 8 and the conductor layer 6, suppress the stress applied to the interfaces 84 and 85 between the via conductor 8 and the conductor layers 6, and effectively decrease separation of the via conductor 8 from the conductor layers 6. The horizontal direction X is a direction parallel to the surface of the insulating layer 7.

Although the narrowed portion 80 shown in FIG. 3 is formed in an elliptic shape, the narrowed portion 80 may be formed in a shape other than an elliptic shape, for example, a polygonal shape, a shape with a waved periphery, or the like, as long as the via conductor 8 is inclined with the horizontal direction X.

The projecting portion 81 is adapted for suppressing separation of the via conductor 8 from the conductor layers 6 when the film layer 7 and the adhesive layer 70 thermally expand. The projecting portion 81 projects in the horizontal direction X and positions in the adhesive layer 70 of the insulating layer 7.

When the semiconductor element 2 is connected to the circuit board 2 through the bumps 4, heat may be applied. On the other hand, in the film layer 71, the constituent atoms of the film layer 71 may be arranged more strongly in the horizontal direction (horizontal direction) X of the film layer 71 than in the thickness direction Y thereof. In such a film layer 71, the thermal expansion coefficient in the horizontal direction X is smaller than that in the thickness direction Y of the film layer 71. Therefore, when heat is applied to the circuit board 2, the film layer 71 tends to thermally expand in the thickness direction Y. However, when the projecting portion 81 of the via conductor 8 positions in the adhesive layer 70, if force is applied to the film layer 71 and the adhesive layer 70 in the thickness direction Y, the projecting portion 80 functions as a stopper against the applied force. As a result, the projecting portion 81 exerts reaction to the applied force due to the presence of the projecting portion 81 in the adhesive layer 70. Therefore, it is possible to suppress separation of the via conductor 8 from the conductor layers 6 and decrease breakage of the circuit board 2.

A joint surface between a conventional via conductor and a conductor layer is an interface between a metal (e.g., copper) constituting the via conductor and a metal (e.g., copper) constituting the conductor layer, and crystals of a metal such as copper may be discontinuously formed in the joint surface. In the via conductor, therefore, the bonding strength at the joint surface tends to become weak as compared with usual strength. Also, the joint surface may be contaminated with foreign substances due to oxidation or insufficient washing in the manufacturing process. In this case, the bonding strength is further decreased. Therefore, the joint surface is a place which has low bonding strength and which is easily contaminated with foreign substances which cause separation. Thus, the via conductor easily separates from the conductor layer at the joint surface therebetween, and particularly, stress is easily concentrated in the joint surface at a narrow end.

In contrast, in the mounted structure 1 shown in FIGS. 1 to 3, stress which is usually concentrated in a joint surface between an end of a via conductor and a conductor layer can be dispersed by forming the narrowed portion 80 in the via conductor 8 so that the stress is also applied to the narrowed portion 80 in the via conductor 8.

Further, the narrowed portion 80 of the via conductor 8 is formed in a shape inclined with respect to the horizontal direction X, and thus the area (circumference) of a section taken along the narrowed portion 80 can be increased as compared with the case in which the narrowed portion 80 is formed in a shape parallel to the horizontal direction X. Therefore, the stress applied to the via conductor 8 can be further dispersed by the narrowed portion 80. As a result, as in the case in which when the circuit board 2 is mounted on a mother board, even when external force is applied to the circuit board 2 and stress is concentrated in the interface (joint surface) between the via conductor 8 and the conductor layer 6, the stress can be reduced by the narrowed portion 80 of the via conductor 8. Consequently, the occurrence of separation of the via conductor 8 from the conductor layer 6 can be decreased, thereby improving yield of the circuit board 2 and the mounted structure 1.

Next, the method for manufacturing the circuit board is described.

First, the core substrate 5 and the film layer 7 are prepared.

The core substrate 5 is formed by heat-press curing a sheet together with a copper foil so that, for example, the thickness dimension is 0.3 mm to 1.5 mm, the sheet being prepared by, for example, weaving glass fibers lengthwise and crosswise into a glass cloth and impregnating the glass cloth with a thermosetting resin, such as an epoxy resin, a bismaleimide triazine resin, a cyanate resin, or the like. In order to decrease thermal expansion of the circuit board 2, the core substrate 5 may be formed using fibers with low thermal expansion, such as fibers of wholly aromatic polyamide, wholly aromatic polyester, or a liquid crystal polymer.

Next, the through holes 50 are formed in the core substrate 5 by generally known drilling so as to pass through the core substrate 5 in the thickness direction Y, and the through hole conductors 51 are formed in the through holes 50 by electroplating. A plurality of through holes are formed, and the diameter is, for example, 0.1 mm to 1 mm.

Further, each of the through holes 50 is filled with a resin, for example, polyimide or the like, to form the insulator 52. Next, a material constituting the conductor layers 6 is deposited on the upper surface 53 and the lower surface 54 of the core substrate 5 by generally known vapor deposition, CVD, or sputtering. Then, resist is applied to each of the surfaces and subjected to exposure and development, and then etching to form the conductor layers 6 on the upper surface 53 and the lower surface 54 of the core substrate 5.

Next, the insulating layers 7 are formed on the upper surfaces of the conductor layers 6. Each of the insulating layers 7 is formed by forming a resin layer serving as the adhesive layer 70 on the surface of the core substrate 5, laminating the film layer 71, and then solidifying the adhesive layer 70 and the film layer 71. The thickness of the insulating layers 7 is, for example, 3 μm to 5 μm.

The resin layer serving as the adhesive layer 70 can be formed by depositing a resin material by, for example, generally known die coating, spin coating, or the like. As the film layer 71, for example, a sheet composed of polybenzoxazole resin as a main component is used. On the other hand, the resin material for forming the adhesive layer 70, for example, a material having a lower thermal decomposition temperature than that of the film layer 71, e.g., polyimide, is used. The resin material for forming the adhesive layer 70 may contain a spherical filler composed of a material with insulation, such as silica.

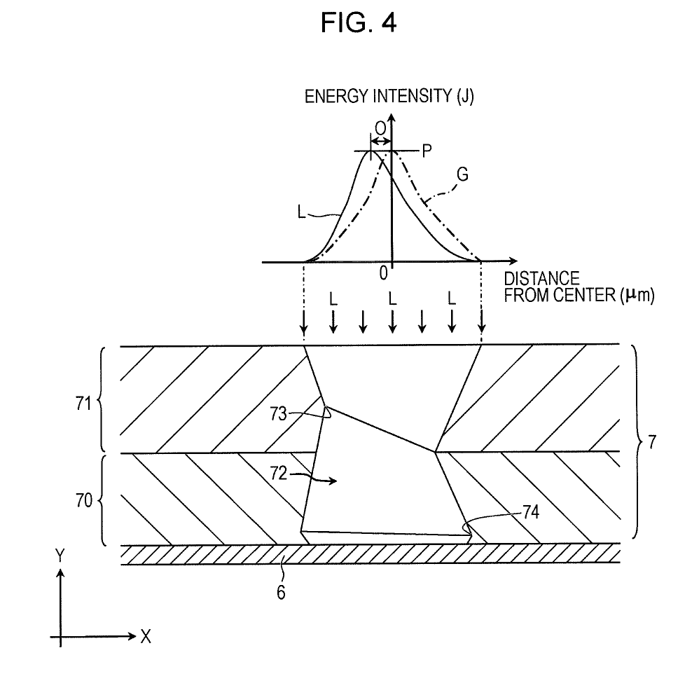

Next, as shown in FIG. 4, the through hole 72 is formed in the insulating layer 7 by irradiation with a laser beam. The laser beam is applied to the surface of the insulating layer 7 in a direction (the thickness direction Y of the insulating layer 7) perpendicular to the surface of the insulating layer 7 using, for example, a YAG laser device or a CO₂ laser device.

As the laser processing method, punching can be used. The punching is a method of decentering the peak P of an energy distribution of laser beam L from the center of the beam. That is, the laser beam L for forming the through hole 72 is laser beam L having an energy distribution having the peak P offset from the center of the through hole 72 to be formed, not Gaussian beam G having energy peak P coinciding with the center of the through hole 72.

The offset amount O of the peak P of the energy distribution of the laser beam L from the center (beam center) of the through hole 72 may be set according to the thickness dimension of the insulating layer 7. For example, when the thickness dimension of the insulating layer 7 is 8 μm to 15 μm, the offset amount O is set to 5 μm or less. This is because when the offset amount O is set to be larger than 5 μm, the conductor layers 6 may be molten at a high temperature and a hole may be formed in the conductor layers 6 before the through hole 72 having a shape which can form the narrowed portion 80 is realized.

When the through hole 72 is formed by punching with the CO₂ laser device, the peak P of the energy distribution of the laser beam L is se to be, for example, 1.0×10⁻³ J to 1.0×10⁻¹ J. The irradiation time of beam B for the insulating layer 7 is set to be, for example, 1.0×10⁻³ second to 1.0 second.

When such a laser beam L is applied to the insulating layer 7, energy of the laser beam L is most concentrated in a portion corresponding to the peak P of the energy distribution rather than the center of the applied laser beam L, and the portion becomes a high temperature. Therefore, the components of the insulating layer 7 sublimate mainly in the portion. As a result, a tapered hole is formed in the film layer 71 so that the width decreases in the downward direction (to the adhesive layer 70) from the upper surface.

The laser beam L passing through the film layer 71 is applied to the adhesive layer 70, and the adhesive layer 71 sublimates mainly in the irradiation position. Since the thermal decomposition temperature of the adhesive layer 70 is lower than that of the film layer 71, the adhesive layer 70 more easily sublimates than the film layer 71. As a result, a tapered hole is formed in the adhesive layer 70 so that the width increases in the downward direction (to the conductor layer 6) from an upper portion.

In this way, a hole formed in the film layer 71 has a tapered shape in which the width decreases to the adhesive layer 70, while a hole formed in the adhesive layer 70 has a tapered shape in which the width increases to the conductor layer 6. Therefore, the through hole 72 has a shape having a narrowed portion 73 near the interface between the adhesive layer 70 and the film layer 71.

On the other hand, the laser beam L passing through the adhesive layer 70 is partially reflected by the conductor layer 6, and the adhesive layer 70 is sublimated by the reflected light. Since the conductor layer 6 has higher heat conductivity than that of the insulating layer 7, the conductor layer 6 more easily escapes heat than the insulating layer 7, and the adhesive layer 70 is little sublimated at the interface between the conductor layer 6 and the insulating layer 7. Therefore, the through hole 72 has a shape having a projecting portion 74 at a position slightly above the conductive layer 6.

Since the peak P of the energy distribution of the laser beam L is offset from the center, the reflected light from a portion of the conductor layer 6 corresponding to higher energy intensity sublimates not only the adhesive layer 6 but also a portion of the film layer 71. Therefore, the narrowed portion 73 of the through hole 72 is inclined with respect to the horizontal direction X of the insulating layer 7.

As the method for forming the through hole 72, instead of the punching, a trepanning process may be used, in which irradiation and non-irradiation are repeated while laser beam is moved.

Next, the via conductor 8 is formed in the through hole 72. The via conductor 8 can be formed by, for example, filling the through hole 72 with a metal such as copper by electroless plating.

The through hole 72 has the narrowed portion 73 and the projecting portion 74 and is tapered between the upper surface of the insulating layer 7 and the narrowed portion 73 so that the width decreases to the narrowed portion 73 and is tapered between the narrowed portion 73 and the projecting portion 74 so that the width increases to the projecting portion 74. Therefore, the via conductor 8 has the narrowed portion 80 and the projecting portion 81 along the shape of the through hole 72 as shown in FIGS. 2 and 3. The via conductor 8 has a first tapered portion between the upper surface of the insulating layer 7 and the narrowed portion 80 so that the width of the via conductor 8 decreases to the narrowed portion 80. Further, the via conductor 8 has a second tapered portion between the narrowed portion 80 and the projecting portion 81 so that the width of the via conductor 8 increases to the projecting portion 81.

When the via conductor 8 is formed by electroless plating or the like, the via conductor 8 includes a single body in which metal crystals are continuously formed. Therefore, the via conductor 8 has good rigidity as compared with discontinued crystals formed by stacking a plurality of metal layers. As a result, the via conductor 8 is little broken by external load, and thus good conductivity can be maintained in the circuit board 2 and the mounted structure 1 of the semiconductor element 3.

In addition, the inner surface of the through hole 72 may be etched with, for example, manganic acid before the via conductor 8 is formed in the through hole 72 of the insulating layer 7. When such etching is performed, fine irregularity is formed in the inner surface of the through hole 72, and thus the inner surface is roughened. As a result, the via conductor 8 formed in the through hole 72 has high adhesion to the inner surface of the through hole 72. Thus, separation of the via conductor 8 from the inner surface of the through hole 72 can be suppressed.

When the adhesive layer 70 contains a spherical filler with insulation, such as silica, the spherical filler is exposed or absent from a portion of the inner surface of the through hole 72, and the portion becomes an irregular surface. As a result, like in the case in which the inner surface of the through hole 72 is etched, the adhesion between the via conductor 8 and the inner surface of the through hole 72 can be improved, and separation of the via conductor 8 can be suppressed.

In addition, the circuit board 2 can be formed by repeating the formation of the conductor layer 6, the formation of the insulating layer 7, the formation of the through hole 72, and the formation of the via conductor 8. Further, the semiconductor element mounted structure 1 can be formed by mounting the semiconductor element 2 on the circuit board 2 through the bumps 3.

The present invention is not limited to the above-mentioned embodiment, and various modifications and improvements can be made within the scope of the gist of the present invention.

1. A circuit board comprising:
an insulating layer; and
a via conductor embedded in the insulating layer;
wherein the via conductor has a narrowed portion inclined with respect to a horizontal direction along a surface of the insulating layer.

2. The circuit board according to claim 1, wherein the narrowed portion is inclined at 10° to 20° with respect to the horizontal direction.

3. The circuit board according to claim 1, wherein between an end of the via conductor in a direction perpendicular to the horizontal direction and the narrowed portion, the width of the via conductor decreases from the end to the narrowed portion.

4. The circuit board according to claim 1, wherein the via conductor has a projecting portion projecting outward.

5. The circuit board according to claim 4, wherein the projecting portion is formed between the end and the narrowed portion.

6. The circuit board according to claim 5, wherein between the projecting portion and the narrowed portion, the width of the via conductor decreases from the projecting portion to the narrowed portion.

7. The circuit board according to claim 1,
wherein the insulating layer includes an adhesive layer and a film layer stacked on the adhesive layer;
the thermal decomposition temperature of the film layer is higher than that of the adhesive layer; and
the difference in thermal decomposition temperature between the film layer and the adhesive layer is 60° C. to 260° C.

8. The circuit board according to claim 7,
wherein thicknesses of the film layer and the adhesive layer are 1 μm to 10 μm; and
the difference in thickness between the film layer and the adhesive layer is 7 μm or less.

9. The circuit board according to claim 7,
wherein the film layer comprises a polybenzoxazole resin; and
the adhesive layer comprises a polyimide resin.

10. The circuit board according to claim 7, wherein a portion of contact with the via conductor in the film layer is rough-surfaced.

11. The circuit board according to claim 7, wherein the adhesive layer contains a spherical filler with insulation.

12. A semiconductor element mounted structure comprising:
the circuit board according to claim 1; and
a semiconductor element mounted on the circuit board and electrically connected to the via conductor.

13. The semiconductor element mounted structure according to claim 12, wherein the semiconductor element is connected to the via conductor through a bump electrically connected to the via conductor.

14. A circuit board comprising:
an insulating layer; and
a via conductor embedded in the insulating layer;
wherein the via conductor has a concave surface which is recessed toward the inside of the via conductor and a cross section of the via conductor which is formed by plotting positions of the recessed portion along the circumferential direction of the via conductor is inclined with respect to a plane parallel to a surface of the insulating layer.
